(19) United States
(12) Patent Application Publication
(10) Pub. No.: US 2024/0422888 A1
(43) Pub. Date: Dec. 19, 2024

(54) EXTREME ULTRAVIOLET LIGHT SOURCE WITH THERMAL STABILIZATION

(71) Applicant: Taiwan Semiconductor Manufacturing Company, LTD., Hsinchu (TW)

(72) Inventors: Chien-Hsing Lu, Tainan (TW); Chih-Chiang Tu, Tauyen (TW); Fei-Gwo Tsai, Taipei (TW); Chih-Wei Wen, Tainan (TW); Hsin-Fu Tseng, Zhubei (TW); Tzu Jeng Hsu, Taoyuan (TW)

(21) Appl. No.: 18/634,221

(22) Filed: Apr. 12, 2024

Related U.S. Application Data
(60) Provisional application No. 63/472,908, filed on Jun. 14, 2023.

(51) Int. Cl. H05G 2/00; G03F 7/00

(52) U.S. Cl. CPC H05G 2/008; G03F 7/70033; G03F 7/70916

(57) ABSTRACT

A laser produced plasma (LPP)-extreme ultraviolet (EUV) light source includes a vacuum chamber, a rotatable crucible disposed in the vacuum chamber with an annular inner surface for carrying a liquid metal, and a laser arranged to apply laser light to the liquid metal carried on the annular inner surface of the rotatable crucible to cause the liquid metal to emit EUV light. The LPP-EUV light source further includes a stationary component disposed in the vacuum chamber and positioned proximate to the annular inner surface of the rotatable crucible or surrounding the rotatable crucible, a coolant fluid delivery inlet or nozzle, and a cooling element secured with the stationary component and including a feature configured to operatively couple with coolant fluid delivered by the coolant fluid delivery inlet or nozzle.

### CROSS-REFERENCE TO RELATED APPLICATIONS

This application claims the benefit of U.S. Provisional Application Ser. No. 63/472,908 filed Jun. 14, 2023, which is incorporated herein by reference in its entirety.

### BACKGROUND

The following relates to extreme ultraviolet (EUV) light sources and EUV light generation methods, to EUV photolithography systems and methods, and related arts.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A, 1B, and 1C diagrammatically illustrate a perspective view of an EUV light source with a rotating liquid metal crucible (FIG. 1A), an exploded isolation perspective view of the catcher assembly of the EUV light source of FIG. 1A with a cooling plate according to an illustrative embodiment (FIG. 1B), and an isolation perspective view of the assembled catcher assembly (FIG. 1C).

FIG. 2 diagrammatically illustrates an isolation perspective view of a variant embodiment of the cooling plate of FIG. 1B.

FIG. 3 diagrammatically illustrates an isolation perspective view of a cooling plate according to another embodiment.

FIGS. 4A, 4B, and 4C diagrammatically illustrate a perspective view of a rotating liquid metal crucible and surrounding stationary ring (FIG. 4A), a perspective view of a shim of the stationary ring (FIG. 4B), and an enlarged perspective view of a portion of the shim illustrating grooves of the shim (FIG. 4C).

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Extreme ultraviolet (EUV) light is used for photolithography in semiconductor fabrication processes intended to produce fine features, i.e., features with small critical dimension (CD). A laser produced plasma (LPP)-EUV light source can be used to produce the requisite EUV light. In an LPP-EUV light source, a laser beam impinges on a suitable liquid metal, such as liquid tin, and the resulting liquid metal plasma emits EUV light. For example, tin plasma emits 13.5 nm EUV light which is a commonly used EUV wavelength for EUV photolithography.

A challenge in EUV lithography is that EUV light is typically not amenable to control using refractive optics due to the very high EUV absorption of most materials.

Hence, the optical train for shaping and directing EUV light employs a series of EUV mirrors. However, EUV light loss at each EUV mirror in the optical train is high. Consequently, it is desirable to have a high brightness (i.e., high power) EUV light source.

One type of LPP-EUV light source employs a droplet injector which sends droplets of the liquid metal through the vacuum within a vacuum chamber at defined time intervals. A pulsed laser is synchronized to strike each liquid metal droplet to generate the EUV-emitting liquid metal plasma.

Another type of LPP-EUV light source employs an annular rotating crucible that carries the liquid metal on an inner surface of the crucible. The laser is arranged to strike the inner surface at a defined stationary location (that is, a location that is stationary respective to the vacuum chamber) to generate the EUV light-emitting liquid metal plasma. Some examples of such an LPP-EUV light source employing liquid tin to generate 13.5 nm EUV light are the TEUS series of LPP-EUV light sources, available from ISTEQ B.V., Eindhoven, The Netherlands. This type of LPP-EUV light source can have certain advantages, for example providing high EUV power, good EUV light output stability, beneficial redirection of liquid metal debris away from the stationary location of EUV light emission, and long LPP-EUV light source lifetime.

The use of a rotating crucible advantageously spreads the energy input from the laser over the inner annular surface of the rotating crucible, to reduce heating and consequent increase in pressure inside the vacuum chamber.

However, it is recognized herein that the use of a rotating crucible can, by itself, sometimes be insufficient to prevent problems in operation of the LPP-EUV light source. In practice, when increasing the laser power to operate such an LPP-EUV light source at high EUV power (as is desirable for some EUV lithography tasks), the temperature at the inner surface of the crucible is observed to rise during use, along with an elevation in the pressure in the vacuum chamber. The liquid tin surface exhibits vibration and stability of the output EUV light decreases.

In embodiments disclosed herein, a cooling clement is provided. The cooling clement may be a cooling plate, or a shim, which is secured with a stationary component that is disposed in the vacuum chamber and positioned proximate to or surrounding the annular rotatable crucible. The cooling element includes a feature configured to operatively couple with coolant fluid delivered by a coolant fluid delivery inlet or nozzle.

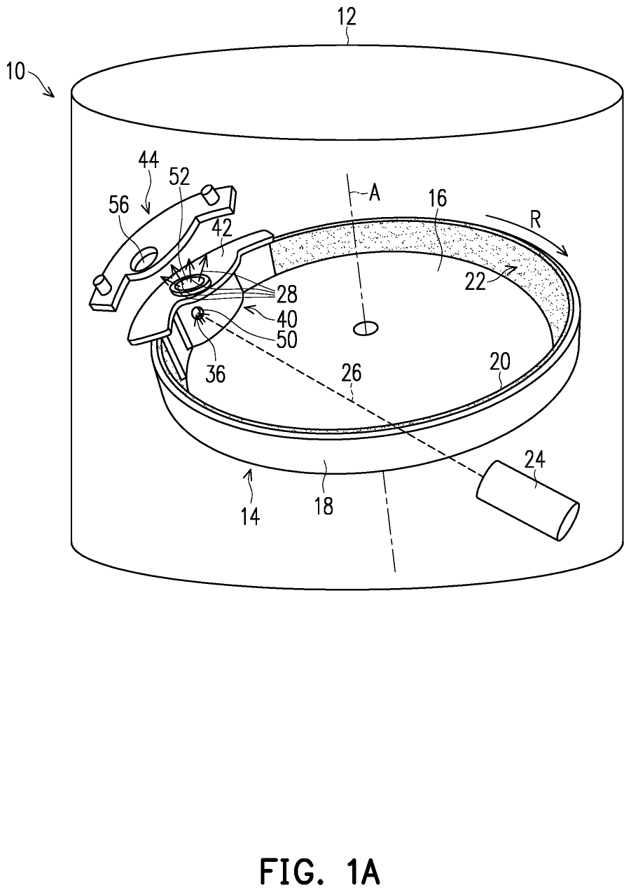

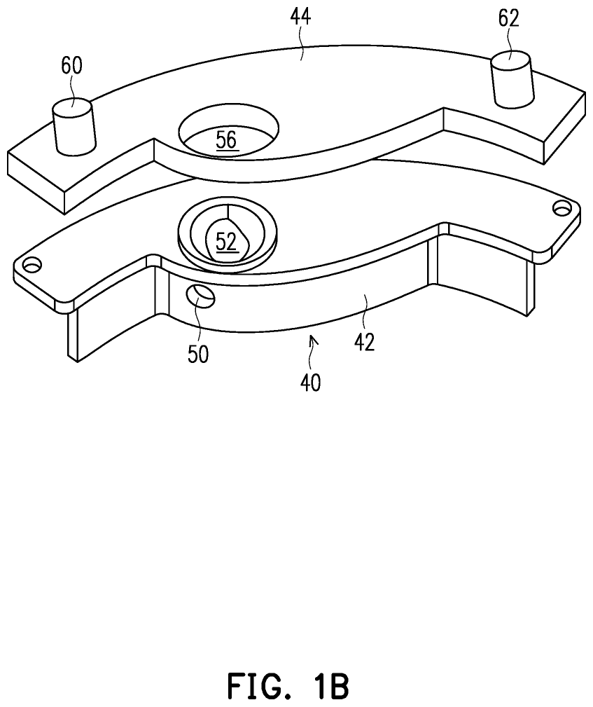

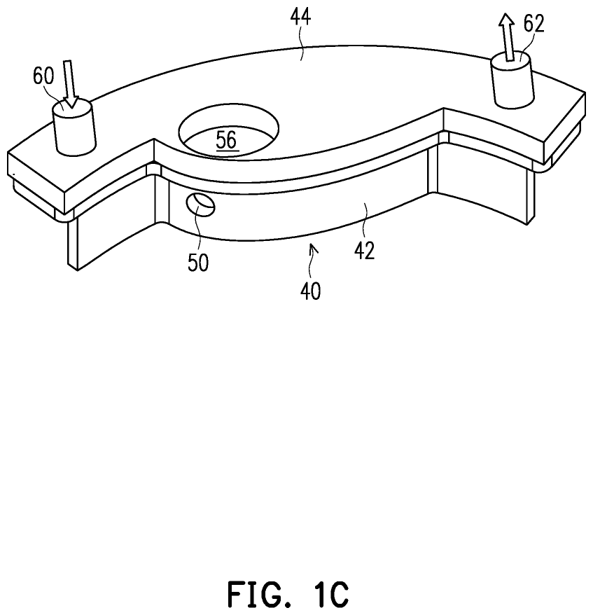

With reference to FIG. 1A, an LPP-EUV light source 10 includes (or, viewed alternatively, has certain components which are contained in) a diagrammatically indicated vacuum chamber 12. The LPP-EUV light source 10 includes a rotatable crucible 14 which, during operation, is rotated by a motor assembly (not shown) about a central axis A. The rotatable crucible 14 includes a flat bottom portion 16 and a sidewall including an annular outer surface 18 and an annular inner surface 20. The rotatable crucible 14 includes an internal heater (not shown) and contains a target metal, such as tin, which is heated to form liquid metal (e.g., liquid tin) that moves outward under centrifugal force due to rotation of the crucible to coat the annular inner surface 20. Hence, the liquid tin or other liquid metal 22 is carried by the annular inner surface 20 during operation of the LPP-EUV light source 10.

A laser 24 is arranged to apply laser light (e.g., a laser beam) 26 to the liquid metal 22 carried on the annular inner surface 20 of the rotatable crucible 14 to cause the liquid metal to interact with the laser light 26 to emit EUV light 28. While the illustrative laser 24 is shown disposed inside the vacuum chamber 12, in other embodiments the laser may be disposed outside the vacuum chamber and direct the laser light through an optical window port of the vacuum chamber.

In more detail, interaction of the laser light 26 with the liquid metal 22 occurs at a fixed location 36 where the laser light 26 impinges on the annular inner surface 20 of the rotating crucible 14 to generate a laser produced plasma at the fixed location 36. As seen in FIG. 1A, the fixed location 36 is partially enclosed by a catcher assembly 40. The laser light 26 may, in some nonlimiting illustrative examples, be a pulsed laser beam with an average power of 10 W-400 W or more. The laser light 26 thus delivers highly concentrated power to the fixed location 36 generating sufficient heat to convert the liquid metal 22 at the fixed location 36 to a laser produced plasma which emits EUV light from the fixed location 36. FIG. 1A diagrammatically depicts emitted EUV light 28. By “fixed location” it is meant the location 36 is fixed relative to the vacuum chamber 12, i.e., it is a fixed location in the frame of reference of the vacuum chamber 12. Said another way, the fixed location 36 does not rotate along with the rotation of the crucible 14. By contrast, as the crucible 14 rotates, the location of impingement of the laser light 26 on the annular inner surface 20 of the rotating crucible 14 changes (in the frame of reference of the crucible 14), so that over time the laser light 26 traces an annular track around the annular inner surface 20 of the rotating crucible 14. The use of the rotating crucible 14 thus is understood to distribute the energy generated by the laser light 26 across an annulus on the inner surface 20 of the crucible 14, thus dispersing the energy over this annulus. It is also noted that the EUV light will generally be emitted omnidirectionally from the fixed location 36, with only a portion of the EUV light collected by suitable EUV optics and delivered to an EUV photolithography system (not shown) and utilized for EUV photolithography. FIG. 1A illustrates EUV light 28 exiting the catcher assembly 40 which is the collected portion of the EUV light.

While this distribution of the energy produced by the rotation of the crucible 14 is beneficial to distribute the laser energy over a larger surface of the crucible, nonetheless, as disclosed herein when increasing the laser power output by the laser 24 to provide high EUV power, the temperature at the inner surface 20 of the rotating crucible 14 is still observed to rise during use, along with a concomitant elevation in the pressure inside the vacuum chamber. The liquid tin surface exhibits vibration and stability of the output EUV light decreases.

With continuing reference to FIG. 1A and with further reference to FIGS. 1B and 1C, an approach for remediating the above problem is disclosed. The LPP-EUV light source 10 of FIG. 1A further includes the catcher assembly 40, which includes a liquid metal debris catcher 42 and a cooling plate 44 secured with the liquid metal debris catcher 42. FIGS. 1A and 1B show exploded views of the catcher assembly 40 in which the cooling plate 44 is spaced apart from the liquid metal debris catcher 42; while, FIGURE IC shows a perspective view of the assembled catcher assembly 40 with the cooling plate 44 secured to the liquid metal debris catcher 42. FIG. 1A also indicates a direction R of rotation of the crucible 14.

As diagrammatically indicated in FIG. 1A, the liquid metal debris catcher assembly 40 is a stationary component that is disposed in the vacuum chamber 12 and is positioned proximate to the annular inner surface 22 of the rotatable crucible 14. The liquid metal debris catcher 42 serves to catch liquid metal debris (such as tin particulates or the like) produced by the interaction between the laser light 26 and the liquid metal (e.g., liquid tin) 22 producing the EUV light-emitting plasma at the fixed location 36. More particularly, the liquid metal debris catcher 42 is positioned near (e.g., partially surrounding) the fixed location 36, and is a stationary component insofar as the liquid metal debris catcher 42 is at a fixed position respective to the frame of reference of the vacuum chamber 12. Said another way, the position of the liquid metal debris catcher 42 does not rotate along with the rotation of the crucible 14. The illustrative liquid metal debris catcher 42 has a laser aperture 50 and an EUV light aperture 52 arranged to pass the laser light 26 and the EUV light 28, respectively. This advantageously enables the liquid metal debris catcher 42 to be positioned close to (e.g., partially surrounding) the fixed location 36 where the EUV light-emitting plasma is produced (and hence, the fixed location 36 is also the location from which the liquid metal debris from that plasma emanates). The illustrative liquid metal debris catcher 42 has a generally arcuate shape that approximately conforms with the curvature of the inner surface 22 of the rotatable crucible 14, again facilitating close placement of the liquid metal debris catcher 42 to the fixed location 36. As the liquid metal debris catcher 42 is located close to the fixed location 36 where the EUV light-emitting plasma is produced, it receives substantial thermal energy from the laser produced plasma, and hence should be made of a material that can withstand this heating. The liquid metal debris catcher 42 may, for example, comprise a metal such as molybdenum, tungsten, or another metal or metal alloy having a suitably high melting point.

With continuing reference to FIGS. 1A-1C, the cooling element in this embodiment comprises the cooling plate 44 which is secured with the liquid metal debris catcher 42 as shown in FIG. 1C. This advantageously places the cooling plate 44 in proximity to the fixed location 36 where the EUV light-emitting plasma is produced, so that it is well positioned for providing cooling functionality. The illustrative metal plate 44 has a generally arcuate shape that approximately conforms with the arcuate shape of the liquid metal debris catcher 42, again facilitating close placement of the liquid metal debris catcher assembly 40 to the fixed location 36. A further advantage of integrating the cooling element with the liquid metal debris catcher 42 is that because the cooling plate 44 is secured with (e.g. bolted to or otherwise fastened to) the liquid metal debris catcher 42, the cooling plate 44 is in intimate thermal contact with the liquid metal debris catcher 42 providing a substantial thermal mass proximate to the fixed location 36 to cool and stabilize the temperature at the fixed location 36. As the cooling plate 44 is located close to the fixed location 36 where the EUV light-emitting plasma is produced, it receives (and advantageously dissipates and/or removes) substantial thermal energy from the laser produced plasma, and hence should be made of a material that can withstand this heating. The cooling plate 44 may, for example, comprise a metal such as molybdenum, tungsten, or another metal or metal alloy having a suitably high melting point.

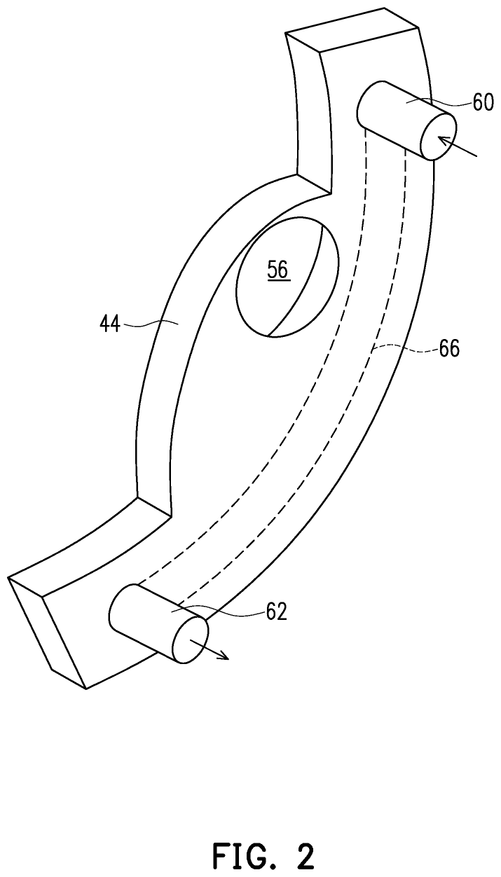

With continuing reference particularly to FIGS. 1B and IC, the cooling plate 44 includes an EUV aperture 56, which is arranged so that the EUV aperture 56 of the cooling plate 44 is aligned with the EUV aperture 52 of the liquid metal debris catcher 42. During operation, the laser light 26 passes through the laser aperture 50 of the liquid metal debris catcher 42, and a portion of the emitted EUV light 28 passes through the EUV apertures 52 and 56 of the respective liquid metal debris catcher 42 and cooling plate 44. In this way, the catcher assembly 40 does not interfere with passage of the laser light 26 or with passage of the EUV light emission 28. A coolant fluid delivery inlet 60 is secured with the cooling plate 44 to deliver coolant fluid into one or more fluid passages (not shown in FIG. 1B, but see FIG. 2) inside the cooling plate 44; and, a fluid outlet 62 is secured with the cooling plate 44 to receive the coolant fluid after passing through the one or more fluid passages inside the cooling plate 44. During operation of the LPP-EUV light source 10, coolant fluid is flowed into the coolant fluid delivery inlet 60, flows through the one or more fluid passages passing through the cooling plate 44 where it absorbs heat emanating from the fixed location 36 where the EUV light-emitting plasma is produced, and then flows out the fluid outlet 62. The coolant fluid may, for example, be a gaseous fluid such as argon gas or another noble gas, nitrogen gas, or so forth; or the coolant fluid may be a liquid fluid such as water or liquid nitrogen. Not shown in FIG. 1B are suitable inlet and outlet coolant fluid lines running from outside the vacuum chamber 12 through fluid ports of the vacuum chamber 12 and connecting to deliver the coolant fluid to the fluid inlet 60 and to remove the coolant fluid output from the fluid outlet 62, respectively. The connections of the fluid lines with the cooling fluid inlet 60 and cooling fluid outlet 62 (as well as with the fluid ports of the vacuum chamber 12) are suitably sealed connection so that the coolant fluid does not leak into the vacuum chamber 12. The flow rate of the coolant fluid can be adjusted based on the amount of heat generated at the fixed location 36 where the EUV light-emitting plasma is produced. The heat generated may be a function of the laser power of the laser 24 applying the laser light 26, for example.

FIG. 2 illustrates an isolation perspective view of the cooling plate 44, including the EUV aperture 56 and the fluid inlet 60 and fluid outlet 62. FIG. 2 also diagrammatically illustrates at least one fluid passage 66 passing through the cooling plate 44. The fluid passage 66 is connected with (i.e., is in fluid communication with) the coolant fluid inlet 60 and the fluid outlet 62 to enable coolant fluid to enter the at least one fluid passage 66 via the inlet 60 and exit from the at least one fluid passage 66 via the outlet 62. The fluid passage 66 may be variously embodied, for example as a pipe embedded in the cooling plate 44, or as a channel drilled or otherwise formed in the bulk molybdenum, tungsten, or other material making up the cooling plate 44. In another contemplated embodiment, the cooling plate 44 may be substantially hollow so that the at least one fluid passage comprises the hollow interior of the cooling plate.

As previously noted with reference to FIG. 1A, the catcher assembly 40 is positioned close to the fixed location 36 where the EUV light-emitting plasma is produced, both so that the liquid metal debris catcher 42 is well positioned to catch liquid metal debris emanating from the fixed location 36 due to laser interactions; and also so that the cooling plate 44 is close enough to the fixed location 36 to absorb and transport heat away from the fixed location 36 of the EUV light-emitting plasma. As the cooling plate 44 is secured with the liquid metal debris catcher 42, there may be highly efficient thermal transport from the liquid metal debris catcher 42 to the cooling plate 44. Optionally, this thermal transport can be enhanced by including thermally conductive material at the interface between the liquid metal debris catcher 42 and the cooling plate 44.

In some embodiments, the catcher assembly 40 is positioned with the liquid metal debris catcher 42 facing the fixed location 36 where the EUV light-emitting plasma is produced so that liquid metal debris emanating from the fixed location 36 impacts on and adheres to the liquid metal debris catcher 42. In this case, the cooling plate 44 operates based in part on heat transfer from the liquid metal debris catcher 42 to the cooling plate 44. In other embodiments, the catcher assembly 40 is positioned with the cooling plate 44 facing the fixed location 36 where the EUV light-emitting plasma is produced. In this case, liquid metal debris emanating from the fixed location 36 impacts on and adheres to the cooling plate 44, so that the cooling plate 44 operatively serves as part of the liquid metal debris catcher 42.

In yet other embodiments, it is contemplated for the liquid metal debris catcher 42 and the cooling plate 44 to be constructed as a single piece; that is, for the cooling plate to be integral with the liquid metal debris catcher. For example, the liquid metal debris catcher can include the at least one fluid passage 66 passing therethrough.

With reference to FIG. 3, an isolation perspective view of a cooling plate 84 according to another embodiment is shown. The cooling plate 84 could be substituted for the cooling plate 44 of the catcher assembly 40 of FIGS. 1B-1C and 2, with the cooling plate 84 suitably secured with the liquid metal debris catcher 42. The illustrative cooling plate 84 is a metal plate that has a generally arcuate shape similar to the shape of the cooling plate 44 of the embodiment of FIGS. 1B-1C and 2, and includes the EUV aperture 56 which is aligned with the EUV aperture 52 of the liquid metal debris catcher 42 when the cooling plate 84 is secured with the liquid metal debris catcher 42

The cooling plate 84 serves a cooling function similar to the cooling plate 44 of the embodiments of FIGS. 1B-1C and 2, but operates in a different manner. The cooling plate 84 does not include the one or more internal fluid passages 66 (see FIG. 2) connected with fluid inlet and outlet 60 and 62. Instead, as shown in FIG. 3, during operation of the cooling plate 84, coolant fluid is flowed out of a nozzle 86 onto a surface 88 of the cooling plate 84. The surface 88 of the cooling plate 84 includes or has formed therein alternating grooves 90 and bumps or ridges 92. As diagrammatically indicated in FIG. 3, the coolant fluid that flows onto the surface 88 spreads out over the surface 88, where the alternating grooves 90 and bumps or ridges 92 improve efficiency of the heat dissipation by the coolant fluid. In the illustrative embodiment, as seen in FIG. 3, the grooves 90 and the ridges 92 are oriented along a portion of the annular inner surface 20 of the crucible 14 proximate to the cooling plate 84. In this orientation, the cooling fluid tends to flow though the grooves 90 thus facilitating heat transfer along the cooling plate 84.

In the embodiment described herein with reference to FIG. 3, the nozzle 86 flows the coolant fluid onto the surface 88 of the cooling plate 84 that includes the alternating grooves 90 and ridges 92. Unlike the embodiments described previously herein with reference to FIGS. 1B-1C and 2, in the embodiment of FIG. 3 the coolant fluid thus flows into the vacuum chamber 12 (see FIG. 1A). This can raise the pressure in the vacuum chamber 12. If the pressure in the vacuum chamber rises too high then it can produce undesirable absorption of EUV light. Hence, the flow rate of the cooling fluid out of the nozzle 86 is suitably controlled to limit the pressure rise. In some nonlimiting illustrative embodiments, the vacuum chamber 12 has a base pressure (without the flow of coolant fluid from the nozzle 86) that is in a range of about 1×10⁻⁴ Pa to 1×10⁻³ Pa, and with the flow of coolant fluid from the nozzle 86 the pressure in the vacuum chamber 12 rises to a pressure that is below 1 Pa. In some nonlimiting illustrative examples, the flow rate of the coolant fluid may be 2000 sccm (i.e., standard cubic centimeters per minute) or lower. The cooling fluid in this embodiment is preferably argon gas or another noble gas, although another type of coolant fluid such as nitrogen gas is also contemplated.

The cooling plate 84 should be made of a material that can withstand the heat emanating from the laser produced plasma at the fixed location 36, and may for example comprise a metal such as molybdenum, tungsten, or another metal or metal alloy having a suitably high melting point. The alternating grooves 90 and ridges 92 can be formed by chemical etching (for example, photolithographically controlled to etch the grooves 90), or computer numerical control (CNC) machining, or so forth. Without loss of generality, the grooves 90 are labeled in FIG. 3 as having width a and height c, and the ridges 92 are labeled as having width b and height d. In some nonlimiting illustrative embodiments, the groove/ridge width ratio a:b of the grooves 90 to ridges 92 is in a range of 10:1 to 1:1. In some nonlimiting illustrative embodiments, the groove/ridge height ratio c:d of the grooves 90 to ridges 92 is in a range of 1:10 to 99:100. Values in these ranges are expected to provide the grooves 90 and ridges 92 with sufficient depth and width to provide the desired improved efficiency of the heat dissipation. If the cooling plate 84 is manufactured from a stock plate in which the surface 88 is originally planar by cutting or etching the grooves 90 into the original planar surface, then the height d of the ridges 92 is the original plate thickness, and the height c of the grooves 90 is the depth into the original planar surface that the grooves 90 are cut or etched.

In the embodiments described thus far, a cooling element comprises a cooling plate 44 or 84, which in the illustrative embodiments is secured to the liquid metal debris catcher 42. More generally, the cooling plate could be secured to another stationary component located close to the fixed location 36 where the laser produced plasma is generated. The cooling fluid is flowed onto the cooling plate 84, or is flowed through the cooling plate 44.

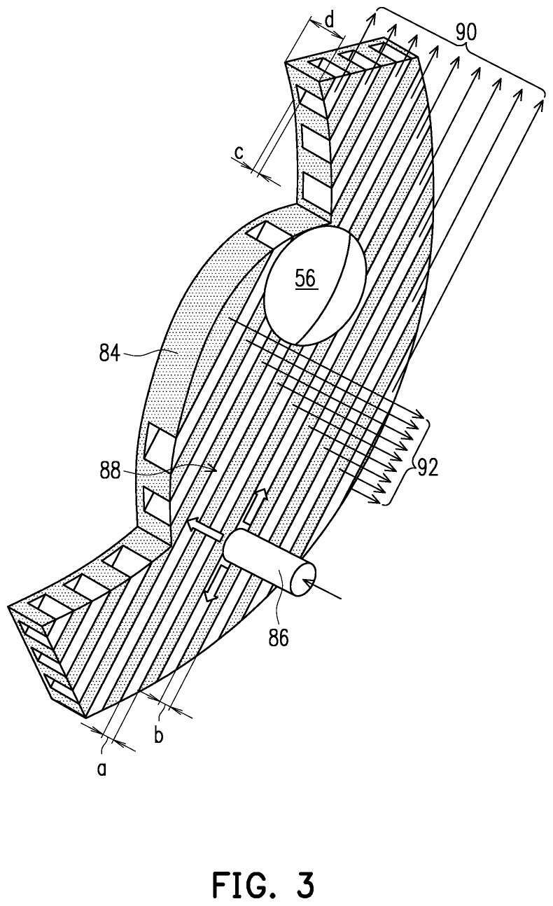

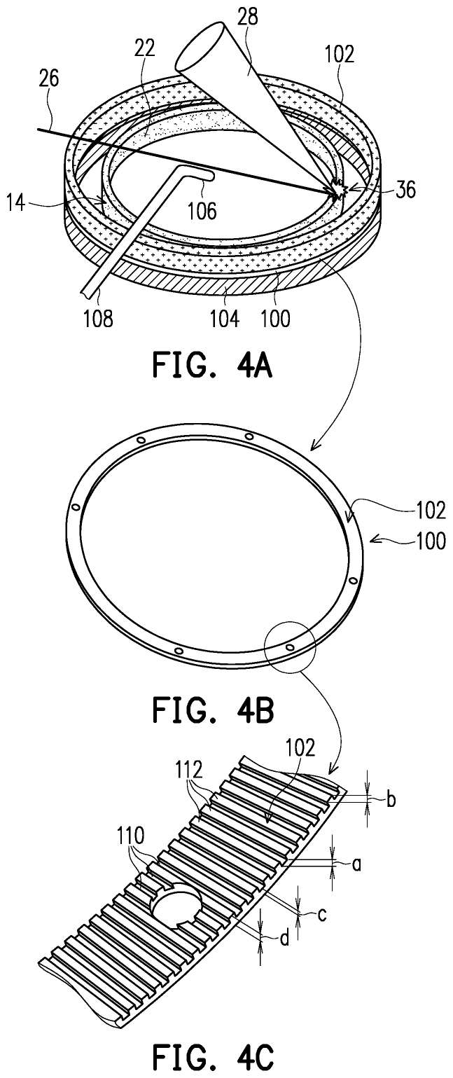

With reference now to FIGS. 4A, 4B, and 4C, in other embodiments the cooling element comprises a shim 100 that is secured with a stationary component 102, 104 surrounding the rotatable crucible 14. FIG. 4A diagrammatically shows a perspective view of a portion of the LPP-EUV light source 10 of FIG. 1A, namely showing the rotatable crucible 14 and depicting the incoming laser light (e.g. laser beam) 26 impinging on the liquid metal 22 on the inner surface of the crucible 14 at the fixed location 36, and the collected portion of the emitted EUV light 28. The LPP-EUV light source of FIG. 4A may include other components depicted in FIG. 1A but not shown in FIG. 4A, such as the vacuum chamber 12, laser 24 (producing the laser beam 26 shown in FIG. 4A), EUV optics 30, 32, 34, and liquid metal debris catcher 42. In the embodiment of FIGS. 4A-4C, the stationary component with which the cooling element 100 is secured includes two rings 102, 104 that surround rotating gantry 14. The rings 102, 104 form a portion of a housing or enclosure that partially houses or encloses the rotating gantry 14. In the embodiment of FIGS. 4A-4C, the cooling element comprises the shim 100. As diagrammatically shown in FIG. 4A, the first and second annular rings 102 and 104 are secured together with the shim 100 interposed between the first and second annular rings. In some nonlimiting illustrative embodiments, the annular rings 102 and 104 may comprise stainless steel, although other materials are contemplated. FIG. 4B presents a perspective view of the shim 100 in isolation. The shim 100 includes features configured to operatively couple with coolant fluid. These features are best seen in FIG. 5, and comprise alternating grooves 110 and ridges 112 formed or disposed on a surface 104 of the shim 100. A coolant fluid delivery nozzle 106 is arranged to deliver coolant fluid into about a center of the vacuum chamber 12 (not shown in FIG. 4A, but sec FIG. 1A), and the coolant fluid then flows outward and across the surface 102 of the shim 100 which includes the alternating grooves 110 and ridges 112. The coolant fluid delivery nozzle 106 may, for example, be disposed at the distal end of a tube or pipe 108 that passes through a port of the vacuum chamber 12 and extends to about the center of the vacuum chamber 12.

FIG. 4C illustrates an enlarged view of a portion of the shim 100 to better illustrate the alternating grooves 110 and ridges 112 on the surface 102 of the shim 100. In operation, the coolant fluid flows outward from the nozzle 106 shown in FIG. 4A. The grooves 110 advantageously provide flow paths or conduits that allow the coolant fluid to pass through the interface between the rings 102 and 104. This helps in defining a fluid flow that passes the coolant fluid onto and over the rotating crucible 14, thus providing cooling of the crucible 14. To facilitate the generally radially outward flow, as best seen in FIG. 4C the alternating grooves 110 and ridges 112 are radially oriented so that the grooves 100 provide radially oriented coolant fluid flow conduits. Without loss of generality, the grooves 110 are labeled in FIG. 4C as having width a and height c, and the ridges 112 are labeled as having width b and height d. In some nonlimiting illustrative embodiments, the groove/ridge width ratio a:b of the grooves 110 to ridges 112 is in a range of 10:1 to 1:1. In some nonlimiting illustrative embodiments, the groove/ridge height ratio c:d of the grooves 110 to ridges 112 is in a range of 1:10 to 99:100. Values in this range are expected to provide the grooves 110 with sufficient width to provide the desired channels for outward flow of the coolant fluid to improve efficiency of the heat dissipation. The shim 100 may also contribute to the cooling by way of thermal conduction through the material of the shim 100. To this end, the shim 100 may, for example, comprise copper, carbon nanotubes (CNTs), or another high thermal conductivity material. The alternating grooves 110 and ridges 112 can be formed by chemical etching (for example, photolithographically controlled to etch the grooves 110), or CNC machining, or so forth.

Similarly to the embodiment of FIG. 3, in the embodiment of FIGS. 4A-4C the nozzle 106 flows the coolant fluid into the vacuum chamber 12. This can raise the pressure in the vacuum chamber 12. If the pressure in the vacuum chamber rises too high then it can produce undesirable absorption of EUV light. Hence, the flow rate of the cooling fluid out of the nozzle 106 is suitably controlled to limit the pressure rise. In some nonlimiting illustrative embodiments, the vacuum chamber 12 has a base pressure (without the flow of coolant fluid from the nozzle 106) that is in a range of about 1×10⁻⁴ Pa to 1×10⁻³ Pa, and with the flow of coolant fluid from the nozzle 106 the pressure in the vacuum chamber 12 rises to a pressure that is below 1 Pa. In some nonlimiting illustrative examples, the flow rate of the coolant fluid may be 2000 sccm or lower. The cooling fluid in this embodiment is preferably argon gas or another noble gas, although another type of coolant fluid such as nitrogen gas is also contemplated.

In the illustrative shim 100 as best seen in FIG. 4B, the alternating grooves 110 and ridges 112 extend along the full 360° circumference of the annular shim 100. This has certain advantages in providing radially symmetrical outward flow of the coolant fluid output from the centrally disposed nozzle 106, and also provides for continual cooling of the entire circumference of the rotating crucible 14. However, in some other embodiments it is contemplated for the alternating grooves 110 and ridges 112 to extend only partway around the circumference of the shim, specifically around a portion of the circumference that is proximate to the fixed location 36 where the EUV light-emitting plasma is produced (and, hence, where maximal laser-induced heating is present).

The illustrated embodiments are representative. More generally, the approach can be implemented as a LPP-EUV light source 10 that includes the vacuum chamber 12, the rotatable crucible 14 disposed in the vacuum chamber 12 and having an annular inner surface 20 configured to carry liquid tin or another liquid metal 22, a laser 24 arranged to apply laser light 26 to the liquid metal 22 carried on the annular inner surface 20 of the rotatable crucible 14 to cause the liquid metal 22 to emit EUV light 26, and a stationary component (e.g., the liquid metal debris catcher 42 or the enclosing annular rings 102 and 104 in the nonlimiting illustrative examples) disposed in the vacuum chamber 12 and positioned proximate to the annular inner surface 20 of the rotatable crucible 14 (e.g., the liquid metal debris catcher 42 being one example) or surrounding the rotatable crucible (e.g., the annular rings 102 and 104 being one example). To provide cooling, such an LPP-EUV light source 10 further includes a coolant fluid delivery inlet or nozzle (e.g., the inlet 60 or the nozzle 86 or nozzle 106), and a cooling element (e.g., the cooling plate 44 of FIGS. 1B and 2) or cooling plate 84 of FIG. 3) or shim (e.g., the shim 100 of FIGS. 4A-4C) secured with the stationary component and including a feature configured to operatively couple with coolant fluid delivered by the coolant fluid delivery inlet or nozzle (e.g., illustrative examples of such a feature include the at least one fluid passage 66 passing through the cooling plate 44, or the alternating grooves 90 and ridges 92 of the cooling plate 84, or the alternating grooves 110 and ridges 112 of the shim 100 of FIGS. 4A-4C).

In the following, some further embodiments are described.

In a nonlimiting illustrative embodiment, a laser produced plasma (LPP)-extreme ultraviolet (EUV) light source includes: a vacuum chamber; a rotatable crucible disposed in the vacuum chamber and having an annular inner surface configured to carry a liquid metal; a laser arranged to apply laser light to the liquid metal carried on the annular inner surface of the rotatable crucible to cause the liquid metal to emit EUV light; a stationary component disposed in the vacuum chamber and positioned proximate to the annular inner surface of the rotatable crucible or surrounding the rotatable crucible; a coolant fluid delivery inlet or nozzle; and a cooling element secured with the stationary component and including a feature configured to operatively couple with coolant fluid delivered by the coolant fluid delivery inlet or nozzle.

In a nonlimiting illustrative embodiment, a method of generating EUV light is disclosed. The method includes: rotating a crucible disposed in a vacuum chamber and having an annular inner surface carrying a liquid metal; generating a laser produced plasma at a fixed location relative to the vacuum chamber by applying laser light to the liquid metal carried on the annular inner surface of the rotating crucible, wherein the laser produced plasma emits EUV light; catching liquid metal debris produced by the generating of the laser produced plasma using liquid metal debris catcher disposed at the fixed location; and cooling the fixed location by flowing a coolant fluid onto or through a cooling plate secured to the liquid metal debris catcher.

In a nonlimiting illustrative embodiment, a method of generating EUV light is disclosed. The method includes: rotating a crucible disposed in a vacuum chamber and having an annular inner surface carrying a liquid metal; generating a laser produced plasma at a fixed location relative to the vacuum chamber by applying laser light to the liquid metal carried on the annular inner surface of the rotating crucible, wherein the laser produced plasma emits EUV light; and cooling the rotating crucible by flowing a coolant fluid into the vacuum chamber and through grooves of alternating grooves and ridges disposed on a surface of a shim that is interposed between first and second annular rings that are secured together and that surround the rotatable crucible.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A laser produced plasma (LPP)-extreme ultraviolet (EUV) light source comprising:
a vacuum chamber;
a rotatable crucible disposed in the vacuum chamber and having an annular inner surface configured to carry a liquid metal;
a laser arranged to apply laser light to the liquid metal carried on the annular inner surface of the rotatable crucible to cause the liquid metal to emit EUV light;
a stationary component disposed in the vacuum chamber and positioned proximate to the annular inner surface of the rotatable crucible or surrounding the rotatable crucible;
a coolant fluid delivery inlet or nozzle; and
a cooling element secured with the stationary component and including a feature configured to operatively couple with coolant fluid delivered by the coolant fluid delivery inlet or nozzle.

2. The LPP-EUV light source of claim 1, wherein:
the stationary component comprises a liquid metal debris catcher positioned proximate to the annular inner surface of the rotatable crucible and having at least one aperture arranged to pass the laser light and the EUV light through the liquid metal debris catcher, and
the cooling element comprises a cooling plate secured with the liquid metal debris catcher.

3. The LPP-EUV light source of claim 2, wherein the cooling plate has at least one aperture aligned with the at least one aperture of the liquid metal debris catcher to pass the laser light and the EUV light through the cooling plate.

4. The LPP-EUV light source of claim 2, wherein:
the feature configured to operatively couple with coolant fluid comprises one or more fluid passages inside the cooling plate,
the coolant fluid delivery inlet or nozzle comprises an inlet that is secured with the cooling plate to deliver the coolant fluid into the one or more fluid passages inside the cooling plate, and
the LPP-EUV light source further comprises a fluid outlet secured with the cooling plate to receive the coolant fluid after passing through the one or more fluid passages inside the cooling plate.

5. The LPP-EUV light source of claim 2, wherein:
the feature configured to operatively couple with coolant fluid comprises alternating grooves and ridges on a surface of the cooling plate; and
the coolant fluid delivery inlet or nozzle comprises a nozzle arranged to deliver the coolant fluid onto the surface of the cooling plate that includes the alternating grooves and ridges.

6. The LPP-EUV light source of claim 5, wherein the grooves and the ridges of the alternating grooves and ridges are oriented along a portion of the annular inner surface of the crucible proximate to the cooling plate.

7. The LPP-EUV light source of claim 5, wherein a ratio a:b is in a range of 10:1 to 1:1, where a is a width of the grooves of the alternating grooves and ridges and b is a width of the ridges of the alternating grooves and ridges.

8. The LPP-EUV light source of claim 5, wherein a ratio c:d is in a range of 1:10 to 99:100, where c is a height of the grooves of the alternating grooves and ridges and d is a height of the ridges of the alternating grooves and ridges.

9. The LPP-EUV light source of claim 1, wherein:
the stationary component comprises first and second annular rings surrounding the rotatable crucible,
the cooling element comprising a shim,
the feature configured to operatively couple with coolant fluid comprises alternating grooves and ridges on a surface of the shim,
the first and second annular rings are secured together with the shim interposed between the first and second annular rings, and
the coolant fluid delivery inlet or nozzle comprises a nozzle arranged to deliver the coolant fluid into the vacuum chamber and across the surface of the shim which includes the alternating grooves and ridges.

10. The LPP-EUV light source of claim 9, wherein a ratio a:b is in a range of 10:1 to 1:1, where a is a width of the grooves of the alternating grooves and ridges and b is a width of the ridges of the alternating grooves and ridges.

11. A method of generating extreme ultraviolet (EUV) light, the method comprising:
rotating a crucible disposed in a vacuum chamber and having an annular inner surface carrying a liquid metal;
generating a laser produced plasma at a fixed location relative to the vacuum chamber by applying laser light to the liquid metal carried on the annular inner surface of the rotating crucible, wherein the laser produced plasma emits EUV light;
catching liquid metal debris produced by the generating of the laser produced plasma using liquid metal debris catcher disposed at the fixed location; and
cooling the fixed location by flowing a coolant fluid onto or through a cooling plate secured to the liquid metal debris catcher.

12. The method of claim 11, wherein the cooling plate includes one or more fluid passages inside the cooling plate, and the cooling comprises flowing the coolant fluid through the one or more fluid passages inside the cooling plate.

13. The method source of claim 11, wherein the cooling plate includes alternating grooves and ridges on a surface of the cooling plate, and the cooling comprises flowing the coolant fluid onto the surface of the cooling plate that includes the alternating grooves and ridges.

14. The method of claim 13, wherein the grooves and the ridges of the alternating grooves and ridges are oriented along a portion of the annular inner surface of the crucible proximate to the cooling plate.

15. The method of claim 13, wherein a ratio a:b is in a range of 10:1 to 1:1, where a is a width of the grooves of the alternating grooves and ridges and b is a width of the ridges of the alternating grooves and ridges.

16. The method of claim 13, wherein a ratio c:d is in a range of 1:10 to 99:100, where c is a height of the grooves of the alternating grooves and ridges and d is a height of the ridges of the alternating grooves and ridges.

17. The method of claim 13, wherein the liquid metal debris catcher and the cooling plate include one or more mutually aligned apertures, and the generating of the laser produced plasma includes applying the laser light through the one or more mutually aligned apertures of the liquid metal debris catcher and the cooling plate, wherein a portion of the emitted EUV light passes through the one or more mutually aligned apertures of the liquid metal debris catcher and the cooling plate.

18. A method of generating extreme ultraviolet (EUV) light, the method comprising:
rotating a crucible disposed in a vacuum chamber and having an annular inner surface carrying a liquid metal;
generating a laser produced plasma at a fixed location relative to the vacuum chamber by applying laser light to the liquid metal carried on the annular inner surface of the rotating crucible, wherein the laser produced plasma emits EUV light; and
cooling the rotating crucible by flowing a coolant fluid into the vacuum chamber and through grooves of alternating grooves and ridges disposed on a surface of a shim that is interposed between first and second annular rings that are secured together and that surround the rotatable crucible.

19. The method of claim 18, wherein a ratio a:b is in a range of 10:1 to 1:1, where a is a width of the grooves of the alternating grooves and ridges and b is a width of the ridges of the alternating grooves and ridges.

20. The method of claim 18, wherein a ratio c:d is in a range of 1:10 to 99:100, where c is a height of the grooves of the alternating grooves and ridges and d is a height of the ridges of the alternating grooves and ridges.
